(19) United States
(12) Patent Application Publication
(10) Pub. No.: US 2014/0151331 A1
(43) Pub. Date: Jun. 5, 2014

(54) DEPOSITION SHIELD FOR PLASMA ENHANCED SUBSTRATE PROCESSING

(71) Applicant: APPLIED MATERIALS, INC., Santa Clara, CA (US)

(72) Inventors: VALENTIN N. TODOROW, Palo Alto, CA (US); MICHAEL D. WILLWERTH, Campbell, CA (US); YING-SHENG LIN, Fremont, CA (US); DAVID PALAGASHVILI, Mountain View, CA (US)

(73) Assignee: APPLIED MATERIALS, INC., Santa Clara, CA (US)

(21) Appl. No.: 13/778,252

(22) Filed: Feb. 27, 2013

Related U.S. Application Data
(60) Provisional application No. 61/733,568, filed on Dec. 5, 2012.

(51) Int. Cl. H01J 37/32

(52) U.S. Cl. CPC H01J 37/32798
USPC 216/67; 156/345.3

(57) ABSTRACT

Methods and apparatus for plasma processing of substrates are provided herein. In some embodiments, a deposition shield for use in processing a substrate having a given width may include a first plate having a first plurality of holes disposed through a thickness of the first plate; and a second plate disposed below the first plate and having a second plurality of holes disposed through a thickness of the second plate, wherein individual holes in the first plurality of holes and the second plurality of holes are not aligned.

### CROSS-REFERENCE TO RELATED APPLICATIONS

This application claims benefit of U.S. provisional patent application Ser. No. 61/733,568, filed Dec. 5, 2012, which is herein incorporated by reference.

### FIELD

Embodiments of the present invention generally relate to plasma enhanced substrate processing apparatus.

### BACKGROUND

During certain substrate processes, byproducts of the process can undesirably deposit on chamber components, such as a chamber lid. During plasma processes that use an inductively coupled plasma source disposed above the chamber lid, accumulation of byproducts (particularly conductive byproducts) can undesirably impact the coupling of RF power to the process gases in the process chamber. Such poor power coupling can result in loss of plasma, increased power requirements to maintain the plasma, and non-uniform plasma creation within the process chamber.

Therefore, the inventors have provided an improved apparatus for plasma processing of substrates in a process chamber.

### SUMMARY

Methods and apparatus for plasma processing of substrates are provided herein. In some embodiments, a deposition shield for use in processing a substrate having a given width may include a first plate having a first plurality of holes disposed through a thickness of the first plate; and a second plate disposed below the first plate and having a second plurality of holes disposed through a thickness of the second plate, wherein individual holes in the first plurality of holes and the second plurality of holes are not aligned.

In some embodiments, a process chamber for processing a substrate may include a chamber body having an inner volume and a dielectric lid; a gas inlet to provide a gas to the inner volume; an RF power source disposed above the dielectric lid to couple RF power to the gas during use; a substrate support disposed in the inner volume opposite the dielectric lid and having a support surface to support a substrate having a given width; and a deposition shield comprising one or more plates of a dielectric material supported in the inner volume that prevents any line of sight between the support surface of the substrate support and the dielectric lid.

In some embodiments, a method of processing a substrate may include forming a plasma in a process chamber using RF power inductively coupled to the plasma from an electrode disposed proximate a dielectric lid of the process chamber; processing a substrate disposed on a substrate support in the process chamber while the plasma is maintained; and providing a deposition shield disposed between the substrate and the dielectric lid while processing the substrate, wherein the deposition shield blocks any line of sight between the substrate and the dielectric lid.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 is a schematic side view of a process chamber having a deposition shield in accordance with some embodiments of the present invention.

FIG. 2 is an isometric view of a deposition shield in accordance with some embodiments of the present invention.

FIG. 3 is a flow chart of a method in accordance with some embodiments of the present invention for processing a substrate in a process chamber having a deposition shield.

FIG. 4 is a schematic side view of a process chamber having a deposition shield in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of present invention provide a deposition shield that can substantially prevent substrate process byproducts (for example, during etch processes) from being deposited on the chamber lid. Deposition of such process byproducts could undesirably cause the lid to become a grounded surface which would reduce the ability of the RF source to couple RF power through the dielectric chamber lid. Thus, embodiments of the present invention advantageously maintain the efficient operation of the process chamber by preventing the weakening of RF power coupling through the dielectric lid.

In some embodiments, to minimize the deposition buildup on the dielectric lid, a deposition shield with one or more dielectric plates is positioned between the dielectric lid and the substrate. The one or more plates block the line of sight from the substrate to the dielectric lid to substantially prevent process byproducts from depositing on the dielectric lid. The process byproducts will preferentially deposit on the plates and not on the dielectric lid. The process chamber will operate with plasma even with the deposition on the deposition shield. Various embodiments of the deposition shield and process chambers having such deposition shields are disclosed below.

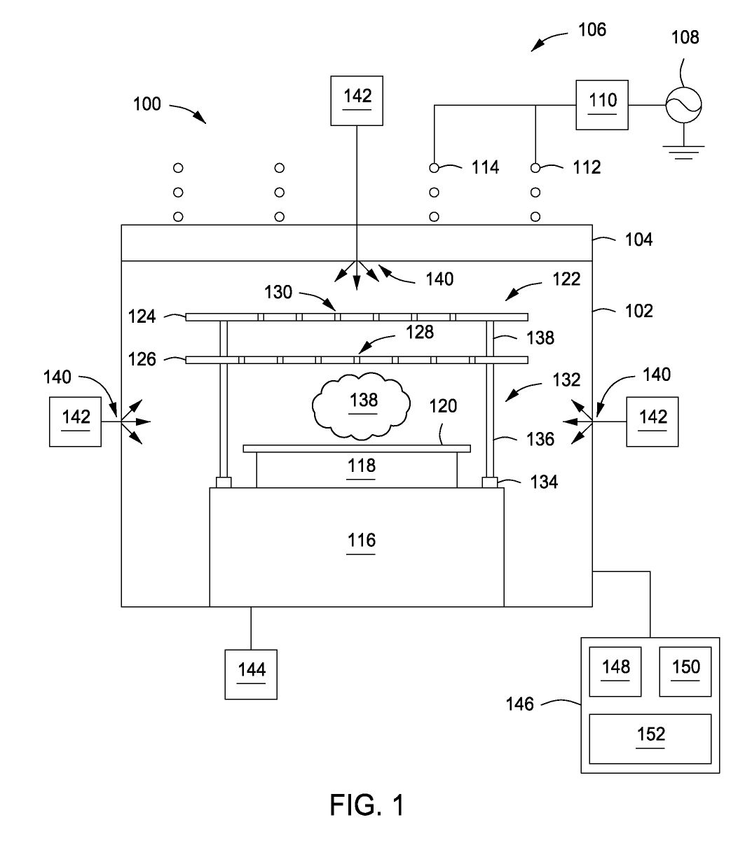

FIG. 1 is a schematic side view of a process chamber 100 having a deposition shield 122 in accordance with some embodiments of the present invention. The process chamber 100 may be configured to perform any plasma assisted substrate process where RF power is coupled into the chamber through a dielectric lid, such as an etching process, for example to etch a conductive material, illustratively, in an MRAM fabrication process. Other processes, including non-etch processes, are contemplated.

The process chamber 100 generally includes a chamber body 102 and the dielectric lid 104. An inductively coupled RF power supply 106 is disposed above the dielectric lid 104 to inductively couple RF power to one or more gases disposed within the process chamber 100 to form and maintain a plasma therein. The inductively coupled RF power source 106 generally includes an RF power supply 108 coupled to one or more electrodes (for example, one or more coil electrodes 112, 114) via a match network 110.

A substrate support 116 is disposed in an inner volume of the process chamber 100 generally opposite the dielectric lid 104. The substrate support 116 generally includes a substrate support surface for supporting substrate 120 having a given width thereon during processing (e.g., a 200 mm, 300 mm, 450 mm, or other diameter semiconductor wafer, or other substrate to be processed). An upper portion of the substrate support 116 may include an electrostatic chuck 118 as well as other components such as an electrode for coupling DC or RF bias power to the substrate 120.

A deposition shield 122 is disposed in the process chamber between the support surface of the substrate support 116 and the dielectric lid 104. The deposition shield 122 may be retained in a desired position in any suitable manner, such as by being supported on the substrate support 116 or other chamber components such as sidewalls or liners of the process chamber 100.

The deposition shield 122 includes one or more dielectric plates that are transparent to the electromagnetic field within the process chamber 100. The dielectric plates may be fabricated from process compatible materials such as quartz or ceramic, or the like. The one or more dielectric plates have a diameter that is greater than that of the substrate.

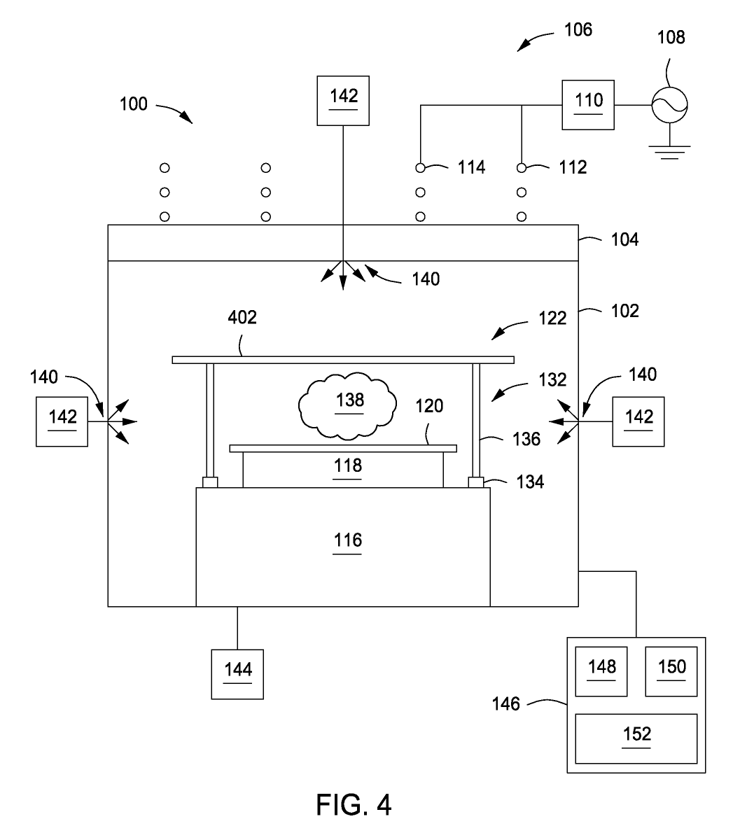

The one or more dielectric plates block any direct line of sight between the support surface of the substrate support 116, or the surface of the substrate 120, and the dielectric lid 104. As used herein, the phrase a direct line of sight refers to a line of sight in a direction normal to the substrate 120 and the dielectric lid 104. For example, in some embodiments, the one or more dielectric plates may include two or more dielectric plates having a plurality of holes formed therethrough, wherein the plurality of holes in each of the dielectric plates are not aligned. In embodiments consistent with FIG. 1, a first dielectric plate 124 and a second dielectric plate 126 are shown each having respective pluralities of holes 128, 130 formed therethrough. The number size and distribution of the pluralities of holes in the dielectric plates may be selected for a desired gas distribution within the process chamber which may be influenced by the location of gas introduction chamber (e.g., from a top of the chamber through the lid, from sides of the chamber, or the like). Alternatively, in some embodiments, the deposition shield 122 may include a single dielectric plate 402 having no holes formed therein, as depicted in FIG. 4. The single dielectric plate 402 has a diameter sufficient to block any direct line of sight between the support surface of the substrate support 116, or the surface of the substrate 120, and the dielectric lid 104.

In some embodiments, a support 132 may be provided to hold the deposition shield 122 and a desired position. In some embodiments, the support may include a plurality of legs 136 support the deposition shield 122 in the desired position. In embodiments where more than one dielectric plate is provided, a plurality of spacers 138 may be provided to maintain each dielectric plate in a spaced apart position with respect to other dielectric plates. In some embodiments, an elongate member may be provided through the second dielectric plate 126 and may be coupled to the first doctor plate 124 such that the portion of the elongate member disposed between the first doctor plate and the second dielectric plate forms the spacer 138 and the portion of the elongate member extending away from the second dielectric plate away from the first doctor plate forms the leg.

In some embodiments, a base ring 134 is disposed atop the substrate support 116. The base ring 134 is a diameter larger than that of the substrate 120. For example, in some embodiments, the substrate support 116 may include an electrostatic chuck 118 and a support ledge disposed about the perimeter of the electrostatic chuck 118. The base ring 134 may be disposed on and/or coupled to the support ledge. The plurality of legs 135 extend from the base ring 134. In some embodiments, the plurality of legs 135 may be coupled to the base ring 134.

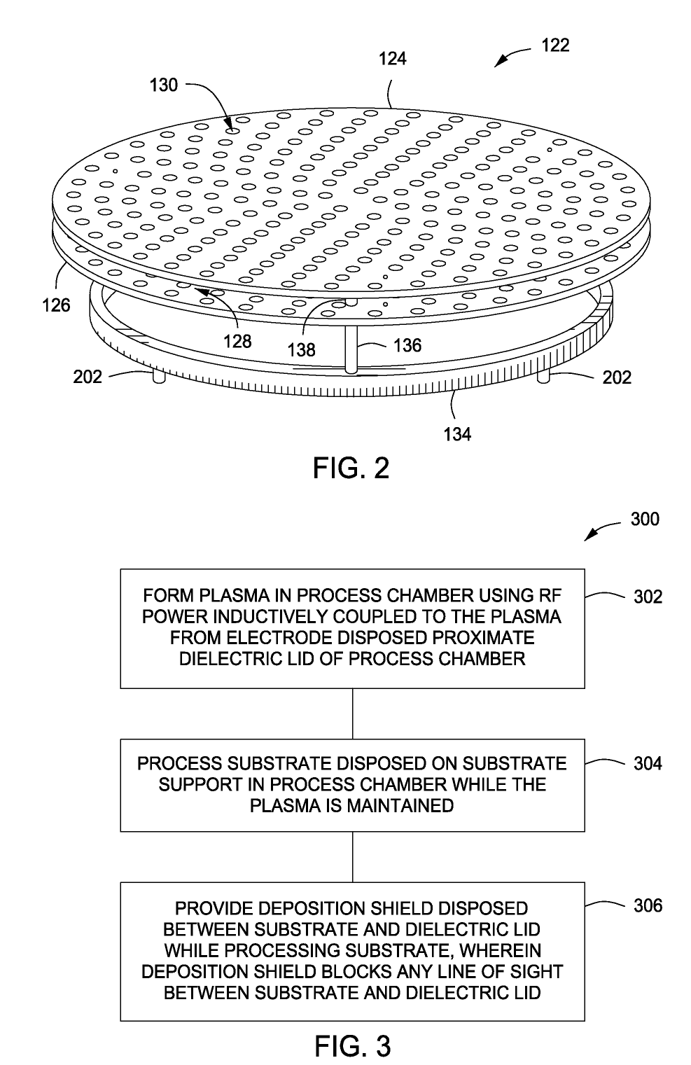

In some embodiments, the base ring may include a plurality of features to facilitate alignment retention the base ring on the substrate support. For example, FIG. 2 is an isometric view of the deposition shield 122 in accordance with some embodiments of the present invention. Specifically, FIG. 2 depicts an embodiment the deposition shield 122 having a first dielectric plate 124 and a second dielectric plate 126. As shown in FIG. 2, in some embodiments, the base ring 134 may include a plurality of features 202 to facilitate alignment and retention of the base ring 134 on the substrate support 116. In some embodiments, three equidistantly spaced features may be provided. In some embodiments, each feature 202 may be a protrusion, for example a cylindrical protrusion, that may interface with a corresponding recess formed in the substrate support 116, for example on the support ledge.

Returning to FIG. 1, one or more inlets 140 may be provided in the process chamber 100 to facilitate providing one or more gases to the inner volume of the process chamber 100. The one or more inlets 140 may be disposed in any suitable location for providing the gas to the inner volume of the process chamber 100. For example as shown in FIG. 1, inlets 140 may be provided in the sidewalls of the chamber body 102, or through the dielectric lid 104. The number and position of the inlets 140 are illustrative, and the number and position of the inlets 140 may be selected depending upon the desired location and distribution of gases within the inner volume of the process chamber 100. For example, in some embodiments, process gases may be provided to a region of the process chamber between the deposition shield 122 and the dielectric lid 104. Alternatively or in combination, process gases may be provided to a region of the process chamber between the deposition shield 122 and the substrate 120. One or more gas supplies 142 may be coupled to the one or more inlets 140 to provide the desired or more gases.

Support equipment 144 may also be coupled to the process chamber 100 such as vacuum pumps additional RF or DC power supplies heat transfer fluid supplies or the like. A controller 146 may be provided to control aspects of the process chamber and generally includes a central processing unit or CPU 148 memory 150 and support circuits 152 software control algorithms may be stored in the memory 150 to control the operation of the process chamber 100, for example to implement any of the inventive methods as described herein.

In operation, the one or more gases are provided to the process chamber 100 while RF power is provided from the RF power supply 108 to the one or more electrodes disposed above the dielectric lid 104 to form a plasma 138 in the process chamber 100. Although shown in a position between the deposition shield 122 and the substrate 120, the plasma may alternatively or in combination be formed in between the deposition shield 122 and the dielectric lid 104 and/or in a region between adjacent plates of the deposition shield 122. The substrate 120 may be processed, for example etched, using the plasma 138 while any process byproduct is either exhausted from the chamber or may deposit on the deposition shield 122 or sidewalls of the process chamber 102. Little or no process byproducts will deposit on the dielectric lid 104.

FIG. 3 is a flow chart of a method 300 in accordance with some embodiments of the present invention for processing a substrate in a process chamber having a deposition shield. The method 300 may be performed in any suitable process chamber having a deposition shield in accordance with the teachings provided herein. For example, the process chamber may be the chamber as described above with respect o FIG. 1. The deposition shield may be as described in any of the embodiments described herein.

The method generally begins at 302 where a plasma may be formed in a process chamber using RF power inductively coupled to the plasma from an electrode disposed proximate a dielectric lid of the process chamber.

At 304, a substrate disposed on a substrate support in the process chamber may be processed while the plasma is maintained. At 306, a deposition shield is disposed between the substrate and the dielectric lid while processing the substrate, wherein the deposition shield blocks any line of sight between the substrate and the dielectric lid.

Any deposition of byproducts from processing the substrate will more likely deposit on the deposition shield as compared to the dielectric lid. Thus, the deposition shield will prevent or reduce deposition on the dielectric lid, which advantageously maintains efficient power coupling from the RF power supply to allow the chamber lid to operate normally as a dielectric window to the RF power above the lid to create the plasma using the inductively coupled plasma source.

While the foregoing is directed to embodiments of the present invention, other and further embodiments of the invention may be devised without departing from the basic scope thereof.

1. A deposition shield for use in processing a substrate having a given width, comprising:
a first plate having a first plurality of holes disposed through a thickness of the first plate; and
a second plate disposed below the first plate and having a second plurality of holes disposed through a thickness of the second plate, wherein individual holes in the first plurality of holes and the second plurality of holes are not aligned.

2. The deposition shield of claim 1, wherein the first plate and the second plate are made of dielectric materials.

3. The deposition shield of claim 1, wherein the first plate and the second plate are made of quartz or ceramic.

4. The deposition shield of claim 1, wherein the first plate and the second plate have a diameter that is greater than the given width of the substrate.

5. The deposition shield of claim 1, further comprising:
a plurality of spacers disposed between the first plate and the second plate to maintain the first and second plates in a spaced apart relation; and
a plurality of legs to support the second plate in a desired position.

6. The deposition shield of claim 5, further comprising:
a plurality of elongate members that pass through the second plate and are coupled to the first plate, wherein a portion of the elongate members that are disposed between the first and second plates form the plurality of spacers and wherein a portion of the elongate members that are disposed below the second plate form the plurality of legs.

7. The deposition shield of claim 5, further comprising:
a base ring disposed at an end of the plurality of legs opposite the second plate, wherein the base ring and the plurality of legs together form a support structure for supporting the second plate in a desired position.

8. The deposition shield of claim 7, wherein the base ring includes a substantially planar surface opposite the second plate and a plurality of features to align and or facilitate retaining the base ring on a surface that the base ring is placed.

9. A process chamber for processing a substrate, comprising:
a chamber body having an inner volume and a dielectric lid;
a gas inlet to provide a gas to the inner volume;
an RF power source disposed above the dielectric lid to couple RF power to the gas during use;
a substrate support disposed in the inner volume opposite the dielectric lid and having a support surface to support a substrate having a given width; and
a deposition shield comprising one or more plates of a dielectric material supported in the inner volume that prevents any line of sight between the support surface of the substrate support and the dielectric lid.

10. The process chamber of claim 9, wherein the gas inlet is configured to provide the gas to a region disposed between the deposition shield and the support surface, and wherein the deposition shield does not have any holes disposed through the first plate.

11. The process chamber of claim 9, wherein the deposition shield comprises:
a first plate having a first plurality of holes disposed through a thickness of the first plate; and
a second plate disposed below the first plate and having a second plurality of holes disposed through a thickness of the second plate, wherein individual holes in the first plurality of holes and the second plurality of holes are not aligned.

12. The process chamber of claim 11, further comprising:
a plurality of spacers disposed between the first plate and the second plate to maintain the first and second plates in a spaced apart relation; and
a plurality of legs disposed on the substrate support to support the second plate in a desired position.

13. The process chamber of claim 12, further comprising:
a plurality of elongate members that pass through the second plate and are coupled to the first plate, wherein a portion of the elongate members that are disposed between the first and second plates form the plurality of spacers and wherein a portion of the elongate members that are disposed below the second plate form the plurality of legs.

14. The process chamber of claim 9, further comprising:
a plurality of legs disposed between the substrate support and the deposition shield to support the deposition shield in a desired position.

15. The process chamber of claim 14, further comprising:
a base ring disposed atop the substrate support and having the plurality of legs extending therefrom.

16. The process chamber of claim 15, wherein the base ring includes a plurality of features to align and or facilitate retaining the base ring on a the substrate support.

17. The process chamber of claim 9, wherein the process chamber is an etch chamber.

18. A method of processing a substrate, comprising:
forming a plasma in a process chamber using RF power inductively coupled to the plasma from an electrode disposed proximate a dielectric lid of the process chamber;
processing a substrate disposed on a substrate support in the process chamber while the plasma is maintained; and
providing a deposition shield disposed between the substrate and the dielectric lid while processing the substrate, wherein the deposition shield blocks any line of sight between the substrate and the dielectric lid.

19. The method of claim 18, wherein processing the substrate comprises forming process byproduct, wherein the process byproduct is predominantly exhausted from the chamber or deposited on the deposition shield or sidewalls of the process chamber.

20. The method of claim 19, wherein processing the substrate further comprises etching the substrate.
